(19) United States
(12) Patent Application Publication
(10) Pub. No.: US 2025/0112170 A1
(43) Pub. Date: Apr. 3, 2025

(54) Transformer Packages Providing Magnetostriction Management

(71) Applicant: Allegro MicroSystems, LLC, Manchester, NH (US)

(72) Inventor: Andrew Thompson, Cheshire (GB)

(73) Assignee: Allegro MicroSystems, LLC, Manchester, NH (US)

(21) Appl. No.: 18/477,755

(22) Filed: Sep. 29, 2023

(51) Int. Cl. H01L 23/552; H01F 17/00; H01F 17/04; H01L 23/31

(52) U.S. Cl. CPC H01L 23/552; H01F 17/0006; H01F 17/04; H01L 23/3107

(57) ABSTRACT

Aspects of the present disclosure include galvanically-isolated (voltage-isolated) transformer-based integrated circuit (IC) packages providing cavities or spaces, which can, in some examples, be formed by preferentially heating the included magnetic core or a material coating the magnetic core. The provision of a space around the magnetic core allows the magnetic core to underdo size changes due to magnetostriction during use without being constrained or substantially constrained, thus, providing for improved magnetic performance. The circuits, ICs and IC packages and modules may include various types of circuits. In some examples, IC packages or modules may include a galvanically-isolated gate driver or other high voltage circuit.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Galvanic isolation can be used to separate circuits in order to protect users from coming into direct contact with hazardous voltages, which can be present for high-power solid state switches.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits. Transformer-based magnetic coupling has presented problems for integrated circuit packages arising from the presence of the transformer structure including transformer core.

### SUMMARY

An aspect of the present disclosure is directed to and includes transformer-based galvanically-isolated (voltage-isolated) integrated circuit (IC) packages providing cavities or spaces for an included magnetic core to undergo size changes due to magnetostriction during operation without being constrained or substantially constrained, thus, providing for improved magnetic performance.

One general aspect of the present disclosure includes an integrated circuit (IC) package with magnetic core. The integrated circuit package can include: a substrate; a magnetic core disposed on the substrate, where the magnetic core includes a soft magnetic material; a plurality of conductive traces, forming first and second coils, configured about the magnetic core; where the first and second coils and magnetic core are configured as a transformer; and a package bodying including an encapsulant material (a.k.a., an encapsulant or encapsulate) configured to encapsulate the magnetic core, where the encapsulant material is configured to provide a cavity surrounding the magnetic core.

Implementations may include one or more of the following features. The cavity of the IC package can be configured to provide a space between an interior surface of the cavity and an exterior surface of the magnetic core. The space may include a gap between the interior surface of the cavity and the exterior surface of the magnetic core. The gap can be between, e.g., about 10 nm to about 100 microns or any sub-range within that broader range, or other practical range or value. The IC package may include at least one semiconductor die disposed on the substrate. The at least one semiconductor die may include an integrated circuit (IC). The IC may include a gate driver. The at least one semiconductor die may include first and second semiconductor die, and the first and second coils each can include a plurality of windings connected to the first and second semiconductor die, respectively. A portion of the encapsulant material can be delaminated from the magnetic core. The substrate may include a lead frame. The substrate may include a printed circuit board (PCB). The substrate may include a plurality of glass thin layers. The substrate may include a plurality of ceramic layers. The substrate may include alumina. The first coil may include a plurality of first coils (e.g., first coils that are separate from each other). The second coil may include a plurality of second coils (e.g., second coils that are separate from each other).

One general aspect can include a method of making an integrated circuit (IC) and transformer package. The method can include: providing a substrate; providing a magnetic core to the substrate, where the magnetic core includes a soft magnetic material; providing first and second coils configured about the magnetic core, where the first and second coils include windings disposed about the magnetic core, and where the first and second coils and magnetic core are configured as a transformer; forming a package body, where the package body includes an encapsulant covering the magnetic core; and causing the magnetic core to expand and separate an interior surface of the encapsulant from an exterior surface of the magnetic core.

Implementations may include one or more of the following features. Causing the magnetic core to expand may include preferentially heating the magnetic core. Preferentially heating the magnetic core may include causing a magnetic flux to flow through the magnetic core. Preferentially heating the magnetic core may include directing energy (e.g., infrared, visible light, ultraviolet, and/or RF energy, etc.) to the magnetic core. The method may include applying a heat-absorbing material to the magnetic core. Preferentially heating the magnetic core may include heating the magnetic core to a temperature in excess of a nominal operational temperature of the magnetic core. The method may include providing at least one semiconductor die to the substrate. The at least one semiconductor die may include first and second semiconductor die, and the first and second coils can be connected to the first and second semiconductor die, respectively. The first and second semiconductor die may include first and second integrated circuits. The first and second integrated circuits are galvanically isolated. The second integrated circuit may include a gate driver. The first coil may include a plurality of first coils. The second coil may include a plurality of second coils.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed examples and embodiments of the present disclose may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principles of the concepts described herein. Furthermore, examples and embodiments are illustrated by way of example and not limitation in the figures, in which:

FIGS. 1A-1B are a top view and side view, respectively, of an example transformer-based IC package structure including a pocket or space providing magnetostriction management for an included magnetic core, in accordance with an embodiment of the present disclosure;

FIGS. 2A-2B show successive steps of fabrication of a transformer-based IC package structure, and corresponding structure, respectively, in accordance with an embodiment of the present disclosure; and

FIG. 3 is shows steps in a method of fabricating transformer-based IC packages providing magnetostriction management using preferential core heating, in accordance with an embodiment of the present disclosure.

### DETAILED DESCRIPTION

The features and advantages described herein are not all-inclusive; additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing transformer-based IC packages and related structures having pockets or cavities for accommodating expansion of the included transformer core due to magnetostriction during operation of the transformer.

Examples and embodiments can include integrated circuit (IC) packages or modules with a voltage-isolation transformer providing galvanic isolation (voltage isolation) between a primary side and a secondary side. Examples and embodiments can include data transmitter and receiver for data communication across a transformer-based isolation barrier. The IC packages and modules may include various types of circuits; in some examples, IC packages or modules may include a galvanically isolated gate driver or other high voltage circuit, etc. First and second semiconductor IC die can be included in the package to provide integrated circuits (ICs), e.g., including, but not limited to, controllers and/or high-voltage circuits such as gate drivers configured to drive an external gate on a MESFET, MOSFET, SIC FET, GaN FET, IGBT, high electron mobility transistor (HEMT), e.g., GaN HEMT, or another load. In some embodiments, the transformers can have step-up, step-down, or power transformer configurations. In some embodiments, a secondary side of a transformer may be a high-voltage side of a step-up transformer configuration.

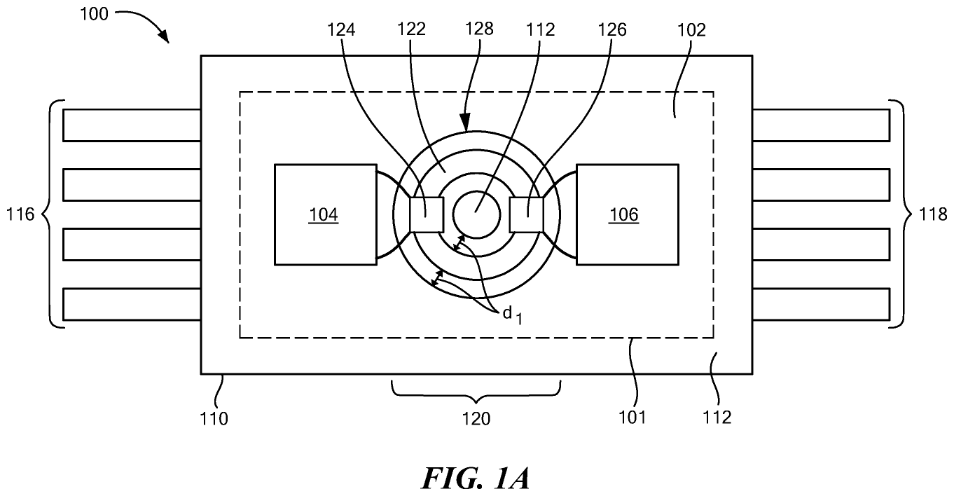

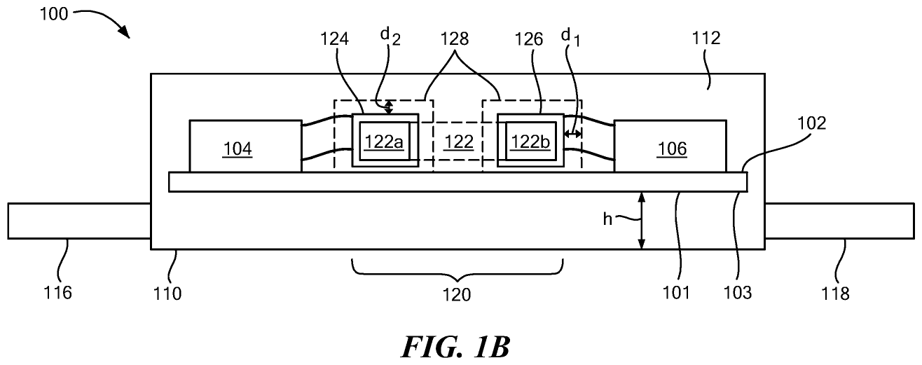

FIGS. 1A-1B are a top view and side view, respectively, of an example transformer-based IC package structure 100 including a cavity or space for magnetostriction management for an included magnetic core, in accordance with an embodiment of the present disclosure. Structure 100 can include a substrate 101 having opposed first and second sides (surfaces) 102, 103. Substrate 101 can include or be formed of a printed circuit board (PCB), in some embodiments. In some embodiments, substrate 101 can include a lead frame, a plurality of glass thin layers, and/or a plurality of ceramic layers. Package structure 100 includes a body 110, which can include molding material 112. One or more semiconductor (IC) die, e.g., first and second die 104 and 106, may be disposed on or supported by (directly or indirectly) substrate 101. As shown in FIG. 1B, substrate 101 may be configured at a selected height, d, within body (package body) 110.

Structure 100 includes a transformer 120 having a magnetic core 122 supported by or disposed on substrate 101 and first (primary) and second (secondary) coils 124 and 126. Transformer 120 can provide galvanic separation (voltage isolation) between first and second die 104, 106.

FIG. 1B shows cross sections 122a-122b of core 122, about which first and second coils 124, 126 are configured (wound), respectively. In some embodiments, transformer 120 can be configured as a step-up transformer providing higher voltage to second coil 126. First and second coils 124, 126 can be connected to first and second die 104, 106, respectively, by suitable conductive structure, e.g., wire bonds, etc. First and second lead sets 116, 118 can provide electrical connections from outside (exterior to) the body 110 to first and second die 104, 106 and any included integrated circuits (ICs), respectively. While lead sets 116, 118 are shown as having the same number of leads, each of the sets may have a different number of leads in other embodiments. Body 110 can include material—e.g., an encapsulant (encapsulate), one or more molding materials, potting material, etc.—that can encapsulate and/or protect the substrate 101, first and second die 104, 106, core 122, and/or first and second coils 124, 126.

While a single first (primary) coil 124 and a single second (secondary) coil 126 are shown, in other embodiments more than one first (primary) coil and/or more than one second (secondary) coil may be used, within the scope of the present disclosure. For example, in some embodiments a first pair of first and second (primary and secondary) coils configured for operation at a first frequency may be wound around a core, while a second pair of first and second (primary and secondary) coils can also be wound around the core and configured for operation at a second frequency, e.g., for operation with other ICs than the ones connected to the first pair of first and second coils. Examples and embodiments can accordingly include transformers with multiple primary (input) coils and/or multiple secondary (output) coils. Some embodiments can include a single first (primary) coil, with multiple second (secondary) coils.

Magnetic core 122 can include soft magnetic material. Any suitable soft magnetic material(s) may be used for magnetic core 122. In some embodiments, magnetic core 122 can include ferrite. In some embodiments, core 122 can include a soft ferromagnetic material. In some embodiments, core 122 can include a soft magnetic material including a non-ferrous (non-iron-containing) material, e.g., ferrite or ceramic without iron. In some embodiments, a nickel or nickel iron alloy, or other electrically conductive soft magnetic material or alloy may be used for core 122. In some embodiments, powdered iron may be used for magnetic core 122. While magnetic core 122 is shown having a circular shape, other shapes (e.g., elliptical/oval, rectangular, square-like, etc.) may be used for core 122 in other embodiments.

As shown, IC package structure 100 provides/includes a cavity or space 128 for magnetic core 122. Cavity 128 allows magnetic core 122 to undergo unconstrained changes in size due to magnetostriction during operation. Thus, cavity 128 can provide for improved magnetic performance of the transformer of IC package 100. Cavity 128 can have a horizonal dimension d₁ and a vertical dimension d₂. As explained in further detail below, cavity 128 can be formed by heating core 122 or a material coating an exterior surface of core 122, causing core 122 to expand against body material 112, e.g., molding material and/or encapsulant. Any suitable material can be used as an encapsulant. In some embodiments, silicone or silicone-containing material can be used as an encapsulant. In some embodiments, epoxy can be used as an encapsulant; other materials may be used in other embodiments. In some embodiments, dimensions d₁ and/or d₂ of cavity 128 can be designed/produced as desired based on heating the core 122 to a certain temperature taking into consideration the coefficient of thermal expansion (CTE) of the core material(s). In some embodiments, the gap afforded by cavity 128 between core 122 and body material 112 can be between about 250 nm to about 10 microns, about 100 nm to about 50 microns, about 10 nm to about 100 microns, etc.; such a gap may have other dimensions in other embodiments in accordance with the present disclosure.

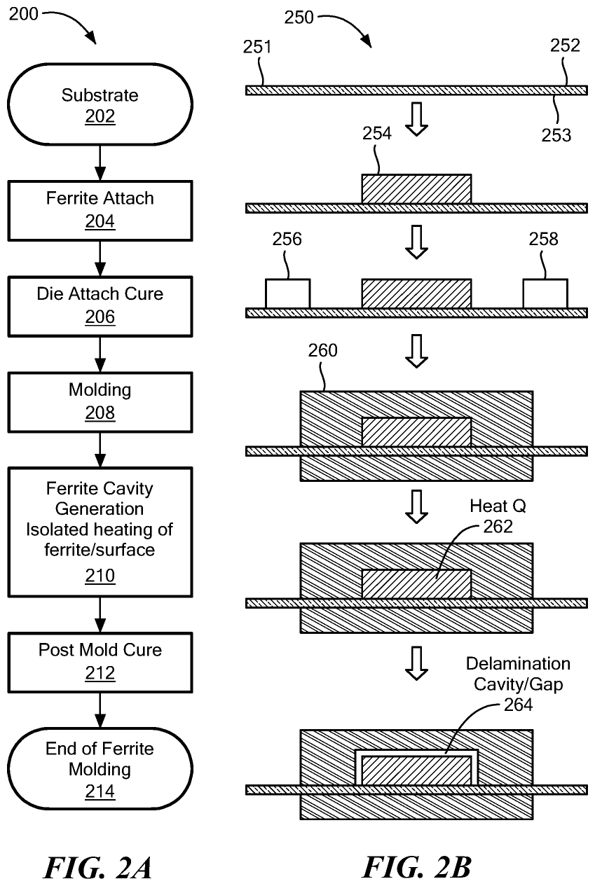

FIGS. 2A-2B show steps of a method 200 of fabrication of a transformer-based IC package structure 250 providing magnetostriction management, and corresponding structure, respectively, in accordance with embodiments of the present disclosure.

As shown for step 202 in FIG. 2A, a substrate can be provided. An exemplary substrate 251 having opposed first and second surfaces 252, 253, is shown in FIG. 2B. A soft magnetic core (e.g., ferrite with iron or without iron), can be attached for step 204 (FIG. 2A). Magnetic core (e.g., ferrite) 254 is shown attached to substrate 251 (FIG. 2B). As shown at step 206, one or more die can be attached to substrate 251, e.g., by curing. First and second die 256, 258 are shown in FIG. 2B. In some embodiments, a die (e.g., second die 258) can be a gate driver configured to drive a gate of a semiconductor power switch (not shown). A molding step can be performed, as shown by 208 in FIG. 2A, forming all or a portion of a package body 260 (FIG. 2B).

As shown at step 210 (FIG. 2A), a cavity can be formed (generated) in the package body by causing the core to expand, e.g., by preferential/isolated heating of the core or a coating on the core relative to the package body material (e.g., molding material). FIG. 2B shows heat (Q) 262 applied to core 254. In some embodiments, a coating having a coefficient of thermal expansion (CTE) greater than that of the core 254 may be applied to the core 254 to facilitate cavity formation. After expansion of core 254 and subsequent cooling, body material (e.g., encapsulant) separates (delaminates) from separates from core 254, producing gap/cavity 264 (FIG. 2B). A post mold curing step 212 can be performed to cure molding material, as an end of core molding 214.

In some embodiments, expansion of the core at step 210 can be controlled so that the size of the resulting cavity 264 will accommodate the nominal expansion of the core due to magnetostriction during nominal (designed-for) operation; an additional volume of cavity 264 can be provided (designed for) as a margin of safety. In some embodiments, the gap afforded by cavity 264 between core 254 and body material can be between, e.g., about 10 nm to about 100 microns, about 250 nm to about 10 microns, etc.; such a gap may have other dimensions in other embodiments.

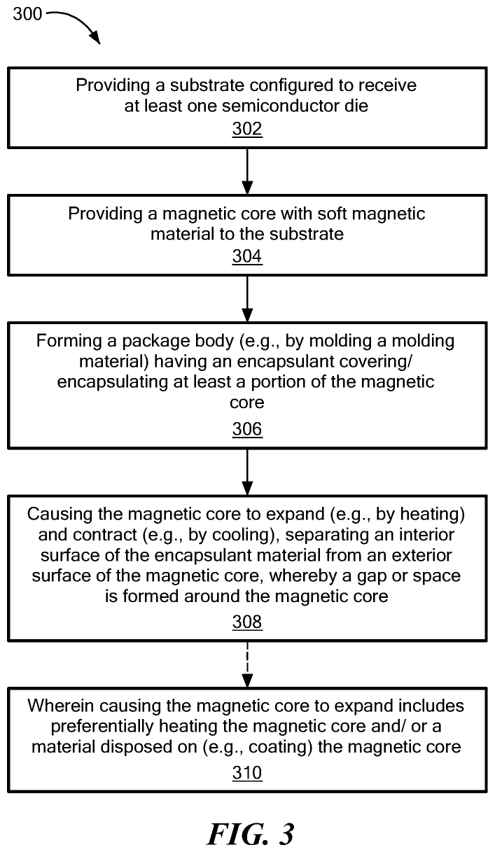

FIG. 3 is shows steps in a method 300 of fabricating a transformer-based IC package providing magnetostriction management using preferential core heating, in accordance with an embodiment of the present disclosure.

Method 300 can include providing a substrate configured to receive at least one semiconductor die, as described at 302. A soft magnetic core can be provided to the substrate, as described at 304. A package body can be formed (e.g., by molding a molding material), covering/encapsulating a portion of the substrate and a portion of the magnetic core, as described at 306. The package body can include material—e.g., an encapsulant, one or more molding materials, potting material, etc.—that can encapsulate and/or protect the substrate, core, and/or coils.

Method 300 can include causing the magnetic core to expand (e.g., by heating) and contract (e.g., by cooling), separating (delaminating) an interior surface of the molding material from an exterior surface of the magnetic core, as described at 308. Cooling-induced contraction (contraction resulting from cooling) of the core can be effected by simply allowing the core to cool after heating or can be facilitated/effected by active cooling, e.g., use of a heat sink or application of a fluid, of the core and/or package body material (e.g., molding material and/or encapsulant). Causing the magnetic core to expand can include preferentially heating the magnetic core, as described at 310. In some embodiments of method 300, the core can be irradiated with radiation at a wavelength preferentially absorbed by the core or material coating the core and less so by the surrounding body material. For example, in some embodiments infrared (IR), visible light, and/or ultraviolet (UV) radiation can be directed to the core. In some embodiments, radio frequency (RF) energy—which can include any RF band, e.g., HF, VHF, THF (THz), etc., or particular wavelength or frequency—can be directed to the core for heating. Any type of energy (frequency or wavelength value or range of values) over the electromagnetic spectrum may be used within the scope of the present disclosure. In some embodiments, a coating material can be applied to the core to absorb incident radiation to cause or facilitate expansion of the core. In some embodiments, a magnetic flux can be provided to the core to cause magnetostriction and/or heating of the core, to cause expansion of the core. In some embodiments, a current can be provided to a conductor in proximity to the core to cause magnetostriction and/or heating of the core, to cause expansion of the core. Expansion of the core can be controlled during method to result in a cavity/gap with desired dimensions relative to the magnetic core, which can allow the core to expand during use without any or significant physical constraint (which could negatively affect magnetic performance).

Accordingly, embodiments of the inventive subject matter can afford various benefits relative to prior art techniques. For example, embodiments and examples of the present disclosure can improve the magnetic performance of isolated gate drivers, or other isolated circuits. For example, in some embodiments, for a given size transformer structure, increased current can be accommodated relative to prior art transformers. For further example, in some embodiments and applications, such improved performance can allow smaller size transformer structure (relative to prior art transformers) for a given performance level (e.g., given/specified amount of current passing through coils wound about the magnetic core, etc.).

Various embodiments of the concepts, systems, devices, structures, and techniques sought to be protected are described above with reference to the related drawings. Alternative embodiments can be devised without departing from the scope of the concepts, systems, devices, structures, and techniques described. For example, embodiments and examples can include transformer coils having an integer number of windings, turns, or loops e.g., 1, 2, etc., while other examples and/or embodiments of the present disclosure may include a different number of transformer windings, turns, or loops, including a fractional number, e.g., 1.5, 2.5, 1.75, 1.8, 2.25, etc. Moreover, while examples and embodiments have been described herein as having a magnetic core disposed on and generally parallel to a substrate, in other embodiments of the present disclosure, a magnetic core can have a different orientation, e.g., disposed generally perpendicular to a substrate; further, in some embodiments, a magnetic core may be disposed through one or more apertures in a substrate.

In some examples and/or embodiments, an IC package can be fabricated or configured such that conductive components, e.g., integrated circuits (ICs) in die 104, 106 of FIGS. 1A-1B, have a desired separation distance between certain parts or features, e.g., to meet internal creepage or external clearance requirements for a given pollution degree rating and/or criterion. For example, a separation distance may be between closest voltage points or voltage regions of the respective circuits, e.g., the low (primary) side and high (secondary) side of a transformer. For further example, such a separation distance may be the distance between any two voltage points/regions between the primary and secondary sides, e.g., between die 104 and die 106 in package 100 in FIGS. 1A-1B. Such a separation distance may be or may be at least 1.2 mm, 1.4 mm, 1.5 mm, 3.0 mm, 4.0 mm, 5.5 mm, 7.2 mm, or 8.0 mm in respective examples. A distance between conductive portions of die or circuit portions can include any insulation covering a conductor, e.g., such as plastic coating of a wire/lead. In some embodiments, distances between parts of an IC package may also be designed and implemented. In some examples and embodiments, the distance between conductor portions between ICs in die, may be or may be at least 1 mm, 1.2 mm, 1.4 mm, 1.5 mm, 2 mm, 4 mm, 6 mm, 7.2 mm, 10 mm, or more (10+mm), e.g., to meet a given voltage isolation requirement, including creepage requirement(s) and/or clearance requirement(s) for a given pollution degree rating as defined by certain safety standards bodies such as the Underwriters Laboratories (UL) and/or the International Electrotechnical Commission (IEC). Distance(s) between any conductor and the exterior environment of the package (e.g., represented by the bottom and/or side in FIG. 1B) can also be selected/implemented as desired for fabrication of packages within the scope of the present disclosure.

In some embodiments, a dielectric material (e.g., gel) may be used for potting and/or protecting packages and/or PCB system assemblies to protect die and/or interconnects from environment conditions and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”, and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications. Any suitable PCB material may be used for a substrate within the scope of the present disclosure; non-limiting examples include FR-4, FR-5, etc.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” indicate, unless expressly stated otherwise herein, any integer number greater than or equal to one, e.g., one, two, three, four, etc.; in some embodiments, where context admits, the terms “one or more” and “at least one” can indicate a fractional value. The term “plurality” indicates any integer number greater than one. The term “connection” can include an indirect “connection” and a direct “connection.”

References in the specification to “embodiments,” “one embodiment,” “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within +20% of a target (or nominal) value in some embodiments, within plus or minus (+) 10% of a target value in some embodiments, within +5% of a target value in some embodiments, and yet within +2% of a target value in some embodiments. The terms “approximately” and “about” may include the target value. The term “substantially equal” may be used to refer to values that are within +20% of one another in some embodiments, within +10% of one another in some embodiments, within +5% of one another in some embodiments, and yet within +2% of one another in some embodiments.

The term “substantially” may be used to refer to values that are within +20% of a comparative measure in some embodiments, within +10% in some embodiments, within +5% in some embodiments, and yet within +2% in some embodiments. For example, a first direction that is “substantially” perpendicular to a second direction may refer to a first direction that is within +20% of making a 90° angle with the second direction in some embodiments, within +10% of making a 90° angle with the second direction in some embodiments, within +5% of making a 90° angle with the second direction in some embodiments, and yet within +2% of making a 90° angle with the second direction in some embodiments.

The disclosed subject matter is not limited in its application to the details of construction and to the arrangements of the components set forth in the description provided herein or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. An integrated circuit (IC) package with magnetic core, the IC package comprising:
a substrate;
a magnetic core disposed on the substrate, wherein the magnetic core includes a soft magnetic material;
a plurality of conductive traces, forming first and second coils, configured about the magnetic core;
wherein the first and second coils and magnetic core are configured as a transformer; and
a package bodying including an encapsulant material configured to encapsulate the magnetic core, wherein the encapsulant material is configured to provide a cavity surrounding the magnetic core.

2. The IC package of claim 1, wherein the cavity is configured to provide a space between an interior surface of the cavity and an exterior surface of the magnetic core.

3. The IC package of claim 2, wherein the space comprises a gap between the interior surface of the cavity and the exterior surface of the magnetic core.

4. The IC package of claim 3, wherein the gap is between about 10 nm to about 100 microns.

5. The IC package of claim 1, further comprising at least one semiconductor die disposed on the substrate.

6. The IC package of claim 5, wherein the at least one semiconductor die comprises an integrated circuit (IC).

7. The IC package of claim 6, wherein the IC comprises a gate driver.

8. The IC package of claim 1, wherein a portion of the encapsulant material is delaminated from the magnetic core.

9. The IC package of claim 5, wherein the at least one semiconductor die comprises first and second semiconductor die, and wherein the first and second coils each includes a plurality of windings connected to the first and second semiconductor die, respectively.

10. The IC package of claim 1, wherein the substrate comprises a lead frame.

11. The IC package of claim 1, wherein the substrate comprises a printed circuit board (PCB).

12. The IC package of claim 1, wherein the substrate comprises a plurality of glass thin layers.

13. The IC package of claim 1, wherein the substrate comprises a plurality of ceramic layers.

14. The IC package of claim 1, wherein the substrate comprises alumina.

15. The IC package of claim 1, wherein the first coil comprises a plurality of first coils.

16. The IC package of claim 1, wherein the second coil comprises a plurality of second coils.

17. A method of making an integrated circuit (IC) and transformer package, the method comprising:
providing a substrate;
providing a magnetic core to the substrate, wherein the magnetic core includes a soft magnetic material;
providing first and second coils configured about the magnetic core, wherein the first and second coils include windings disposed about the magnetic core, and wherein the first and second coils and magnetic core are configured as a transformer;
forming a package body, wherein the package body includes an encapsulant covering the magnetic core; and
causing the magnetic core to expand and separate an interior surface of the encapsulant from an exterior surface of the magnetic core.

18. The method of claim 17, wherein causing the magnetic core to expand comprises preferentially heating the magnetic core.

19. The method of claim 18, wherein preferentially heating the magnetic core comprises causing a magnetic flux to flow through the magnetic core.

20. The method of claim 19, wherein preferentially heating the magnetic core comprises directing energy to the magnetic core.

21. The method of claim 20, further comprising applying a heat-absorbing material to the magnetic core.

22. The method of claim 18, wherein preferentially heating the magnetic core comprises heating the magnetic core to a temperature in excess of a nominal operational temperature of the magnetic core.

23. The method of claim 17, further comprising providing at least one semiconductor die to the substrate.

24. The method of claim 23, wherein the at least one semiconductor die comprises first and second semiconductor die, and wherein the first and second coils are connected to the first and second semiconductor die, respectively.

25. The method of claim 24, wherein the first and second semiconductor die comprise first and second integrated circuits.

26. The method of claim 25, wherein the first and second integrated circuits are galvanically isolated.

27. The method of claim 25, wherein the second integrated circuit comprises a gate driver.

28. The method of claim 17, wherein the first coil comprises a plurality of first coils.

29. The method of claim 17, wherein the second coil comprises a plurality of second coils.
